(19) United States
(12) Patent Application Publication
(10) Pub. No.: US 2010/0052148 A1
(43) Pub. Date: Mar. 4, 2010

(54) PACKAGE STRUCTURE AND PACKAGE SUBSTRATE

(75) Inventor: Shih-Ping Hsu, Taoyuan (TW)

Correspondence Address: EDWARDS ANGELL PALMER & DODGE LLP, P.O. BOX 55874, BOSTON, MA, 02205, US

(73) Assignee: UNIMICRON TECHNOLOGY CORPORATION, Taoyuan (TW)

(21) Appl. No.: 12/541,253

(22) Filed: Aug. 14, 2009

(30) Foreign Application Priority Data
Sep. 3, 2008 (TW) 097133692

(51) Int. Cl. H01L 23/498

(52) U.S. Cl. 257/692; 257/E23.07

(57) ABSTRACT

Provided are a package structure and a package substrate, including: a substrate body having a plurality of matrix-arranged electrical contact pads formed on at least one surface thereof, wherein a solder mask layer is formed on said surface and has a plurality of openings for exposing the electrical contact pads, respectively; a first electroless-plated layer disposed on the electrical contact pads, on the walls of the openings and at the peripheries of the openings; and a second electroless-plated layer disposed on the first electroless-plated layer, the first and second electroless-plated layers constituting a recessed electrical connection structure. By forming the even electroless-plated layers on the electrical contact pads. The invention overcomes drawbacks of the prior art, namely breakage of interfaces between solder bumps and electrical contact pads and even damage of the package structure otherwise caused by excessive differences in stress between the solder bumps.

### BACKGROUND OF THE INVENTION

1. Field of the Invention

The present invention relates generally to package structures and package substrates, and more particularly, to an electrical connection structure on a surface of a package substrate.

2. Description of Related Art

Along with the development of electronic industries, electronic products have a trend towards miniaturization and multi-function, and accordingly various packages are developed. Conventionally, an IC semiconductor chip is mounted on a package substrate or a leadframe, electrically connected to the package substrate or the leadframe by wire bonding, and then packaged by means of an encapsulant, so as to form a semiconductor package. Unlike wire bonding technology, flip-chip package technology introduced by IBM in the early 1960s is characterized by mounting a semiconductor chip on a package substrate and establishing electrical connection between the semiconductor chip and the package substrate through a plurality of solder bumps array-arranged on the package substrate, and then filling an underfill material between the package substrate and the semiconductor chip so as to reinforce mechanical connection therebetween. The flip-chip package technology increases layout density and increases I/O connections per unit area so as to achieve an integration effect, and reduces the overall package size so as to meet the miniaturization requirement. In addition, the flip-chip package technology decreases the impedance and enhances the electrical performance of the package by dispensing with gold wires.

FIGS. 1A to 1E shows a method for fabricating a conventional package structure. As shown in FIG. 1A, a substrate body 10 is provided, and at least one surface 10a thereof has a plurality of electrical contact pads 101. A solder mask layer 11 is formed on the surface 10a, and a plurality of openings 110 are formed in the solder mask layer 11 for exposing the electrical contact pads 101, respectively. As shown in FIG. 1B, a solder material 14 is formed on the electrical contact pads 101 by screen printing using a screen mask 18 with openings 180. As shown in FIG. 1C, the solder material 14 is reflowed so as to form solder bumps 14′. As shown in FIG. 1D, the solder bumps 14′ are coined to the same height. As shown in FIG. 1E, a semiconductor chip 15 having an active surface 15a is provided, wherein the active surface 15a has a plurality of electrode pads 151 with bumps disposed thereon. The bumps are electrically connected to the solder bumps 14′, and the bumps and the solder bumps 14′ are reflowed to form solder bumps 14″. Further, an underfill material 17 is filled between the semiconductor chip 15 and the solder mask layer 11. Thus, a package structure is obtained.

Although the solder bumps 14′ are coined, there are great differences in height, area and volume between the solder bumps 14′, which results in excessive differences in stress between the solder bumps 14′ during packaging and reliability tests, thereby causing interfaces between the solder bumps 14′ and the electrical contact pads to crack easily to the detriment of the package structure as a whole. Further, in case of uneven distribution of the size of the solder bumps on the chip or the substrate or a surfeit of the solder material 14, bridging and short circuits are likely to occur to the reflow process. Also, a fine pitch and a high pin count prevent filling of the underfill material 17.

Therefore, it is imperative to overcome the above drawbacks of the prior art.

### SUMMARY OF THE INVENTION

In view of the above drawbacks of the prior art, an objective of the present invention is to provide a package structure and a package substrate so as to prevent breakage of interfaces between solder bumps and electrical contact pads and even damage of the whole package structure caused by excessive differences in stress between the solder bumps.

Another objective of the present invention is to provide a package structure and a package substrate so as to increase the bonding force between the semiconductor chip and the substrate body.

A further objective of the present invention is to provide a package structure and a package substrate so as to balance stresses applied on the solder material.

In order to achieve the above and other objectives, the present invention provides a package structure, which comprises: a substrate body, wherein a plurality of electrical contact pads is arranged in a matrix on at least one surface of the substrate body, a solder mask layer is formed on the surface and has a plurality of openings for exposing the electrical contact pads, respectively; a first electroless-plated layer disposed on the electrical contact pads, on the walls of the openings and at the peripheries of the openings; a second electroless-plated layer disposed on the first electroless-plated layer, the first and second electroless-plated layers constituting a recessed electrical connection structure; and a semiconductor chip having an active surface, wherein a plurality of electrode pads is formed on the active surface, a solder material disposed between the electrode pads and the second electroless-plated layer, and filled in the recessed electrical connection structure and connected to the second electroless-plated layer.

In the above-described structure, the first electroless-plated layer is made of copper (Cu), and the second electroless-plated layer is made of tin (Sn), nickel/palladium/gold (Ni/Pd/Au), or nickel/gold (Ni/Au).

The above-described structure further comprises an underfill material filled between the active surface of the semiconductor chip and the solder mask layer, and further comprises a plurality of solder bumps disposed on the second electroless-plated layer and connected to the solder material.

In the above-described structure, the solder bumps located in the outer region of the matrix are larger than the solder bumps located in the inner region of the matrix, the solder bumps located in the corner regions of the matrix are larger than the solder bumps located in the other regions of the matrix, and the solder bumps located in the outer region of the matrix and the solder bumps located in the inner region of the matrix are made of the same or different materials. Further, the solder bumps located in the outer region of the matrix have a material stress less than that of the solder bumps located in the inner region of the matrix.

The present invention further provides another package structure, which comprises: a substrate body with at least a surface thereof having a plurality of electrical contact pads arranged thereon in a matrix, the surface having a solder mask layer disposed thereon, wherein the solder mask layer has a plurality of openings for exposing the electrical contact pads, respectively; a first electroless-plated layer disposed on the electrical contact pads, on the walls of the openings and at the peripheries of the openings; a second electroless-plated layer disposed on the first electroless-plated layer, the first and second electroless-plated layers constituting a recessed electrical connection structure; a semiconductor chip having an active surface with a plurality of electrode pads provided thereon, wherein a plurality of metal bumps are provided on the electrode pads and the metal bumps extended into the recessed electrical connection structure constituted by the first and second electroless-plated layers; and a solder material disposed between the metal bumps and the second electroless-plated layer so as for the solder material to be filled in the recessed electrical connection structure and electrically connected to the second electroless-plated layer.

Regarding the package structure, the metal bumps are made of gold (Au), copper (Cu), nickel (Ni), or lead (Pb).

The present invention provides another package structure, which comprises: a substrate body, wherein a plurality of electrical contact pads is arranged in a matrix on at least one surface of the substrate body, a solder mask layer is formed on the surface and has a plurality of openings for exposing the electrical contact pads, respectively; a first electroless-plated layer disposed on the electrical contact pads, on the walls of the openings and at the peripheries of the openings; a second electroless-plated layer disposed on the first electroless-plated layer, the first and second electroless-plated layers constituting a recessed electrical connection structure; a plurality of solder bumps disposed on the second electroless-plated layer; and a semiconductor chip having an active surface, wherein a plurality of electrode pads is formed on the active surface, a plurality of metal bumps is disposed on the electrode pads and electrically connected to the solder bumps on the second electroless-plated layer.

Regarding the package structure, the metal bumps are made of gold (Au), copper (Cu), nickel (Ni), or lead (Pb).

The present invention further provides a package substrate, which comprises: a substrate body, wherein a plurality of electrical contact pads is arranged in a matrix on at least one surface of the substrate body, a solder mask layer is formed on the surface and has a plurality of openings for exposing the electrical contact pads, respectively; a first electroless-plated layer disposed on the electrical contact pads, on the walls of the openings and at the peripheries of the openings; and a second electroless-plated layer disposed on the first electroless-plated layer, the first and second electroless-plated layers constituting a recessed electrical connection structure.

Therein, the first electroless-plated layer is made of copper (Cu), and the second electroless-plated layer is made of tin (Sn), nickel/palladium/gold (Ni/Pd/Au), or nickel/gold (Ni/Au).

The substrate further comprises a plurality of solder bumps disposed on the second electroless-plated layer.

In the above-described substrate, the solder bumps located in the outer region of the matrix are larger than the solder bumps located in the inner region of the matrix, the solder bumps located in the corner regions of the matrix are larger than the solder bumps located in the other regions of the matrix, and the solder bumps located in the outer region of the matrix and the solder bumps located in the inner region of the matrix are made of the same or different materials. Further, the solder bumps located in the outer region of the matrix have a material stress less than that of the solder bumps located in the inner region of the matrix.

Therefore, the present invention mainly involves forming even electroless-plated layers on the electrical contact pads of the substrate body so as to overcome the conventional drawbacks of breakage of interfaces between the solder bumps and the electrical contact pads and even damage of the whole package structure caused by excessive differences in stress between the solder bumps during packaging and reliability tests due to different heights, areas and sizes of the solder bumps. Further, the first and second electroless-plated layers are formed in a much wider area than the electrical contact pads so as to increase the area of contact with the solder bumps, thereby increasing the bonding force between the semiconductor chip and the substrate body. Furthermore, by increasing sizes or decreasing stresses of the solder bumps located in the outer region or corner regions of matrix, the stresses applied on the solder bumps are balanced so as to increase the reliability of the package structure.

### BRIEF DESCRIPTION OF DRAWINGS

FIGS. 1A to 1E are sectional views showing a conventional package structure and a method for fabricating the same;

FIGS. 2A to 2G are sectional views showing a package substrate and method for fabricating the same according to the present invention;

FIG. 2G′ is a top view of FIG. 2G;

FIG. 2G″ is a top view of FIG. 2G according to another embodiment; and

FIGS. 3A to 3D are sectional views showing package structures according to the present invention.

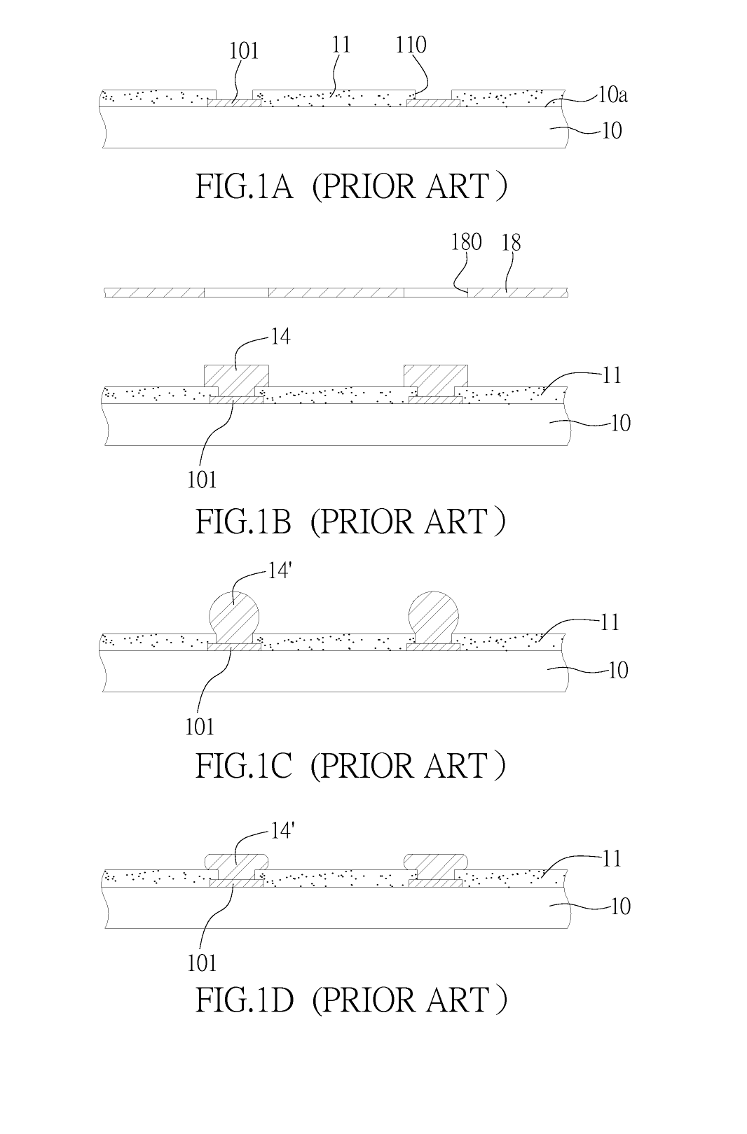

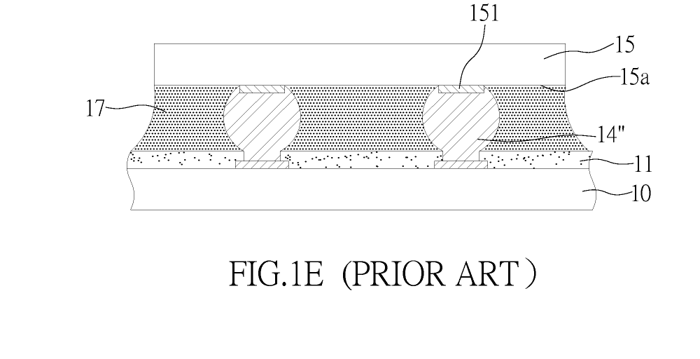

### DETAILED DESCRIPTION OF PREFERRED EMBODIMENTS

The following illustrative embodiments are provided to illustrate the disclosure of the present invention, these and other advantages and effects can be apparent to those in the art after reading this specification.

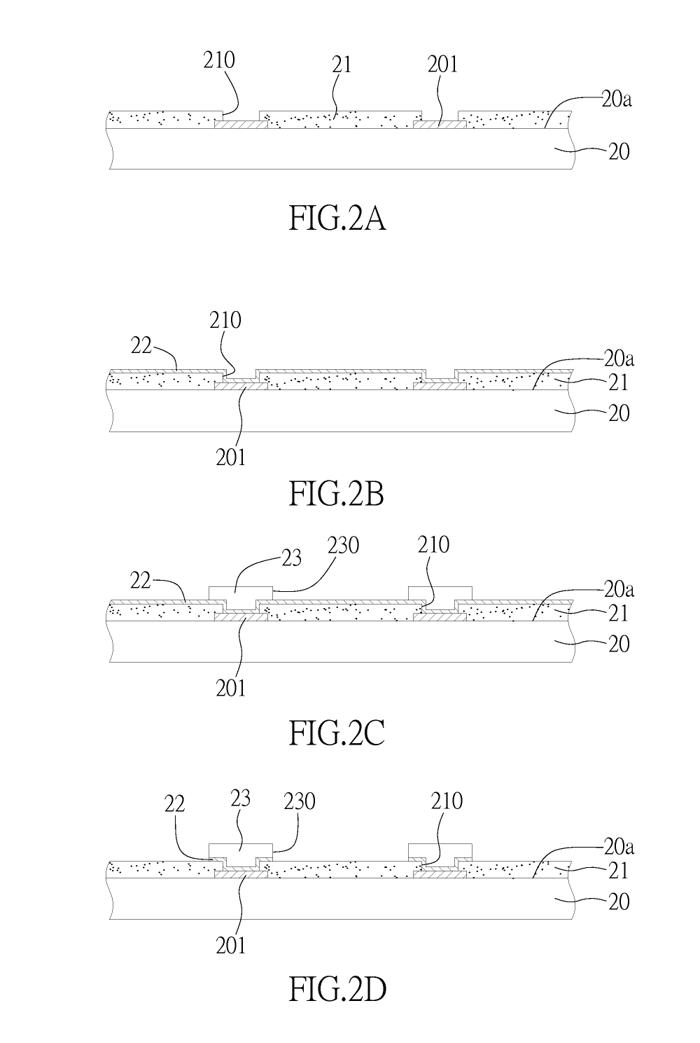

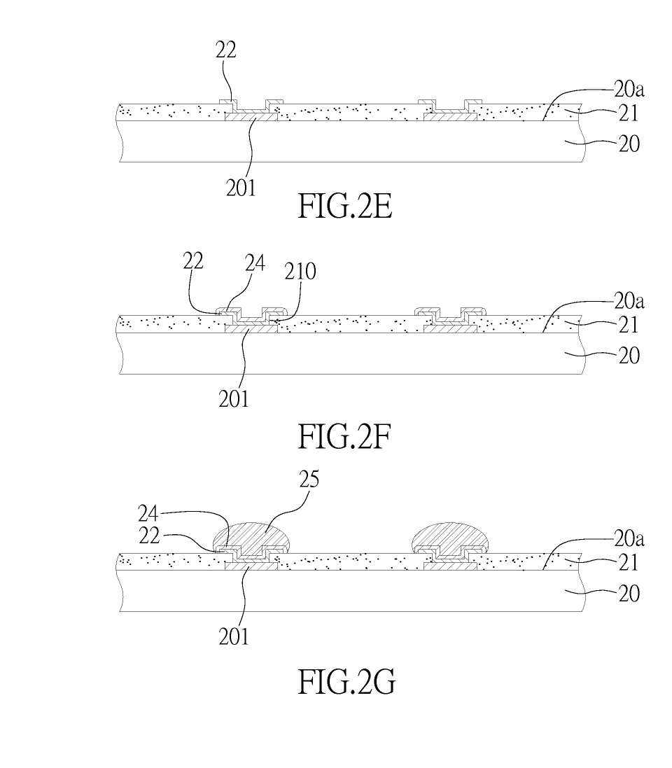

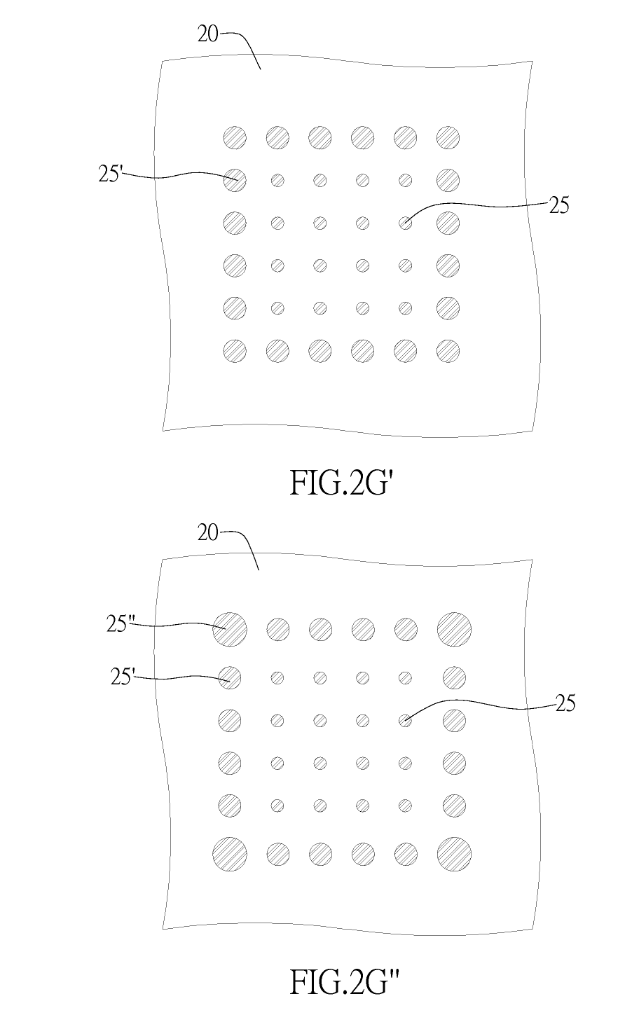

FIGS. 2A to 2G are sectional views showing a package substrate and method for fabricating the same according to the present invention.

Referring to FIG. 2A, a substrate body 20 is provided. As shown in the drawing, a plurality of electrical contact pads 201 are arranged in a matrix on at least one surface 20a of the substrate body 20, and a solder mask layer 21 is formed on the surface 20a, thereby allowing a plurality of openings 210 to be formed in the solder mask layer 21 for exposing the electrical contact pads 201, respectively.

Referring to FIG. 2B, a first electroless-plated layer 22 made of copper (Cu) is formed on the solder mask layer 21, on the electrical contact pads 201 and on the walls of the openings 210.

Referring to FIG. 2C, a resist layer 23 is formed on the first electroless-plated layer 22, and a plurality of resist layer removal regions 230 are formed in the resist layer 23 for exposing the first electroless-plated layer 22 outside the peripheries of the openings 210.

Referring to FIG. 2D, the first electroless-plated layer 22 in the resist layer removal regions 230 is removed by laser processing or chemical etching.

Referring to FIG. 2E, the resist layer 23 is removed to expose the first electroless-plated layer 22.

Referring to FIG. 2F, a second electroless-plated layer 24 is formed on the first electroless-plated layer 22, and the first and second electroless-plated layers 22, 24 constitute a recessed electrical connection structure. The second electroless-plated layer 24 is made of tin (Sn), nickel/palladium/gold (Ni/Pd/Au), or nickel/gold (Ni/Au).

Referring to FIG. 2G, a solder material is formed on the second electroless-plated layer 24 by ball implantation or printing and then reflowed to form solder bumps 25. The solder bumps 25 are made of tin (Sn), lead (Pb), silver (Ag), copper (Cu), zinc (Zn), bismuth (Bi), nickel (Ni), palladium (Pd), or gold (Au) by screen printing or ball implanting according to the prior art. In addition, since solder bumps located in an outer region of a package suffer the strongest stresses and are easy to break, the solder bumps on the substrate body are suitably processed such that stresses on the solder bumps are balanced, thereby improving the reliability of the package structure. For example, the solder bumps 25′ located in the outer region of the matrix are larger than the solder bumps 25 located in the inner region of the matrix, as shown in FIG. 2G′. Meanwhile, the solder bumps 25″ located in the corner regions of the matrix are larger than the solder bumps 25′ that are not located in the corner regions of the matrix, as the solder bumps 25′ and the solder bumps 25″ are formed by screen printing using a screen mask with openings of different sizes or by implanting balls of different sizes according to the prior art, as shown in FIG. 2G″. Further, the solder bumps 25′ located in the outer region of the matrix and the solder bumps 25 located in the inner region of the matrix are made of the same or different materials. For example, the solder bumps 25′ located in the outer region of the matrix are made of tin/lead (Sn/Pb), while the solder bumps 25 located in the inner region of the matrix are made of tin/silver (Sn/Ag). The solder bumps 25′ located in the outer region of the matrix have a material stress less than that of the solder bumps 25 located in the inner region of the matrix.

The present invention further discloses a package substrate, which comprises: a substrate body 20, wherein a plurality of matrix-arranged electrical contact pads 201 is formed on at least one surface 20a of the substrate body 20, a solder mask layer 21 is formed on the surface 20a and a plurality of openings 210 is formed in the solder mask layer 21 for exposing the electrical contact pads 201, respectively; a first electroless-plated layer 22 disposed on the electrical contact pads 201, on the walls of the openings 210, and at the peripheries of the openings 210; and a second electroless-plated layer 24 disposed on the first electroless-plated layer 22, the first electroless-plated layer 22 and the second electroless-plated layer 24 constituting a recessed electrical connection structure.

In the above-described package substrate, the first electroless-plated layer 22 is made of copper (Cu), and the second electroless-plated layer 24 is made of tin (Sn), nickel/palladium/gold (Ni/Pd/Au), or nickel/gold (Ni/Au).

In the above-described structure, a plurality of solder bumps 25 is disposed on the second electroless-plated layer 24. The solder bumps 25 are made of tin (Sn), lead (Pb), silver (Ag), copper (Cu), zinc (Zn), bismuth (Bi), nickel (Ni), palladium (Pd), or gold (Au). The solder bumps 25 are made by screen printing or ball implanting according to the prior art.

As described above, the solder bumps 25′ located in the outer region of the matrix are larger than the solder bumps 25 located in the inner region of the matrix, as shown in FIG. 2G′. Meanwhile, the solder bumps 25″ located in the corner regions of the matrix are larger than the solder bumps 25′ that are located in the other regions of the matrix, as shown in FIG. 2G″. The solder bumps of different sizes are formed by screen printing using a screen mask with openings of different sizes or implanting balls of different sizes. Further, the solder bumps 25′ located in the outer region of the matrix and the solder bumps 25 located in the inner region of the matrix are made of the same or different materials. For example, the solder bumps 25′ located in the outer region of the matrix are made of tin/lead (Sn/Pb), while the solder bumps 25 located in the inner region of the matrix are made of tin/silver (Sn/Ag). The solder bumps 25′ located in the outer region of the matrix have a material stress less than that of the solder bumps 25 located in the inner region of the matrix. The solder bumps located in the inner region of the matrix are formed first by printing or ball implantation and then the solder bumps located in the outer region of the matrix are formed by printing or ball implantation.

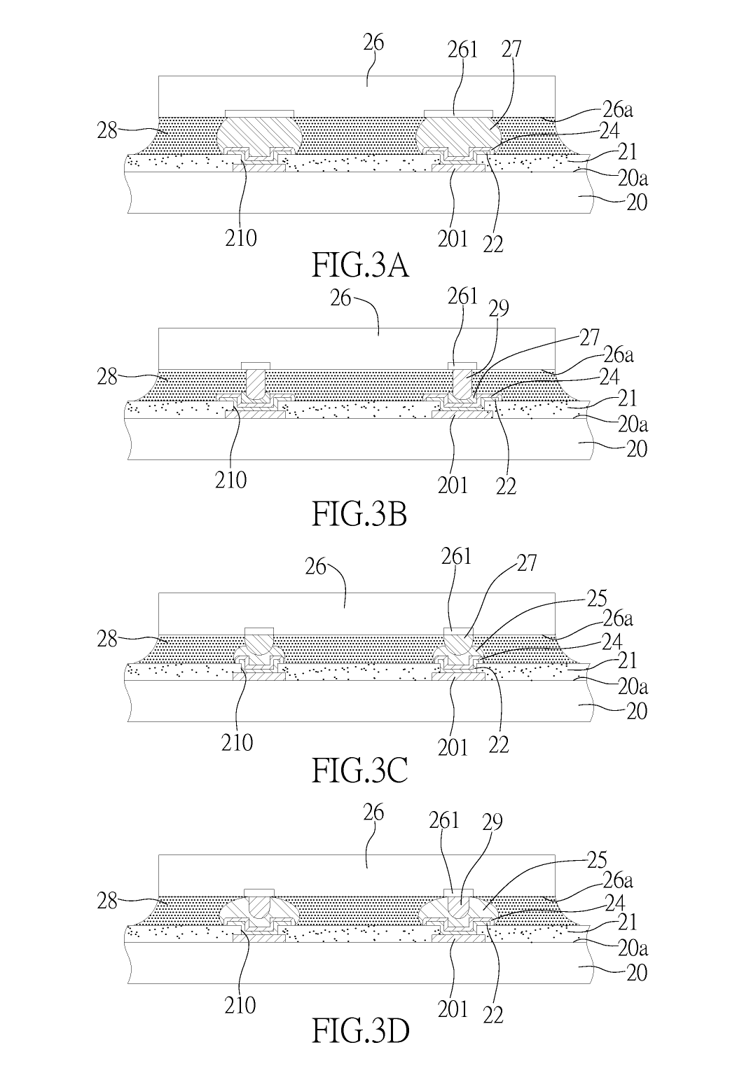

Referring to FIG. 3A, a semiconductor chip 26 with an active surface 26a is provided, and the active surface 26a has a plurality of electrode pads 261 thereon. As shown in the drawing, a solder material 27 is disposed between the electrode pads 261 and the second electroless-plated layer 24, filled in the recessed electrical connection structure, and electrically connected to the second electroless-plated layer 24, thereby mounting the semiconductor chip 26 on the substrate body 20. Further, an underfill material 28 is filled between the semiconductor chip 26 and the solder mask layer 21, to finalize fabrication of a package structure, as shown in the drawing.

Referring to FIG. 3B, a plurality of metal bumps 29 are disposed on the electrode pads 261 of the semiconductor chip 26, and the metal bumps 29 extended into the recessed electrical connection structure constituted by the first electroless-plated layer 22 and second electroless-plated layers 24, and a solder material 27 is disposed between the metal bumps 27 and the second electroless-plated layer 24, and electrically connected to the second electroless-plated layer 24. As shown in the drawing, the metal bumps 29 extend deep into the recessed electrical connection structure constituted by the first electroless-plated layer 22 and the second electroless-plated layer 24, thereby allowing the semiconductor chip 26 to be firmly mounted on the substrate body 20. Further, an underfill material 28 is filled between the semiconductor chip 26 and the solder mask layer 21 so as to form another package structure, as shown in the drawing.

In the package structures of FIGS. 3A and 3B, a precise wafer process is performed such that the solder material 27 on the electrode pads has same height and volume, and the solder material 27 is further electrically connected to the substrate body 20 of an even thickness, thereby avoiding the conventional drawbacks of uneven stresses and solder bridging due to a surfeit of solder material.

Referring to FIG. 3C, a semiconductor chip 26 having an active surface 26a is provided, and the active surface 26a has a plurality of electrode pads 261 thereon. As shown in the drawing, a solder material 27 is disposed between the electrode pads 261 and the second electroless-plated layer 24, and a plurality of solder bumps 25 are disposed on the second electroless-plated layer 24 and connected to the solder material 27. The solder material 27 is electrically connected to the solder bumps 27, thereby mounting the semiconductor chip 26 on the substrate body 20. Further, an underfill material 28 is filled between the semiconductor chip 26 and the solder mask layer 21. Thus, a package structure is obtained.

Referring to FIG. 3D, a plurality of solder bumps 25 are disposed on the second electroless-plated layer 24, and a plurality of metal bumps 29 are disposed on the electrode pads 261 of the semiconductor chip 26. As shown in the drawing, the semiconductor chip 26 is mounted on the substrate body 20 with the metal bumps 29 electrically connected to the solder bumps 25. Further, an underfill material 28 is filled between the semiconductor chip 26 and the solder mask layer 21. Thus, a package structure is obtained.

The present invention further discloses a package structure, which comprises: a substrate body 20, wherein a plurality of matrix-arranged electrical contact pads 201 are formed on at least one surface 20a of the substrate body 20, a solder mask layer 21 is formed on the surface 20a and has a plurality of openings 210 for exposing the electrical contact pads 201, respectively; a first electroless-plated layer 22 disposed on the electrical contact pads 201, on the walls of the openings 210, and at the peripheries of the openings 210; a second electroless-plated layer 24 disposed on the first electroless-plated layer 22, the first electroless-plated layer 22 and the second electroless-plated layer 24 constituting a recessed electrical connection structure; and a semiconductor chip 26 mounted on the second electroless-plated layer 24, wherein the semiconductor chip 26 has an active surface 26a with a plurality of electrode pads 261, a solder material 27 being disposed on the electrode pads 261 and electrically connected to the second electroless-plated layer 24.

In the above-described package structure, the solder mask layer 21 is made of a photosensitive resin or non-photosensitive resin such as green paint or a dielectric layer. The first electroless-plated layer 22 is made of copper (Cu), and the second electroless-plated layer 24 is made of tin (Sn), nickel/palladium/gold (Ni/Pd/Au), or nickel/gold (Ni/Au).

The above-described structure further comprises a plurality of metal bumps 29 disposed on the electrode pads 261 of the semiconductor chip 26, wherein the solder material 27 is disposed on the metal bumps 29. The metal bumps 29 are made of gold (Au), copper (Cu), nickel (Ni), or lead (Pb). The above structure further comprises an underfill material 28 filled between the active surface 26a of the semiconductor chip 26 and the solder mask layer 21; and a plurality of solder bumps 25 disposed on the second electroless-plated layer 24. The solder bumps 25 are made of tin (Sn), lead (Pb), silver (Ag), copper (Cu), zinc (Zn), bismuth (Bi), nickel (Ni), palladium (Pd), or gold (Au). The solder bumps 25 are made of screen printing or ball implantation of the prior art.

As described above, the recessed electrical connection structure allows the metal bumps 29 of the semiconductor chip 26 to slide therein so as to increase the bonding force between the semiconductor chip 26 and the substrate body 20.

As described above, the solder bumps 25′ located in the outer region of the matrix are larger than the solder bumps 25 located in the inner region of the matrix. Meanwhile, the solder bumps 25″ located in the corner regions of the matrix are larger than the solder bumps 25′ that are located in the other regions of the matrix. The solder bumps of different sizes are formed by screen printing using a screen mask with openings of different sizes or implanting balls of different sizes. Further, the solder bumps 25′ located in the outer region of the matrix and the solder bumps 25 located in the inner region of the matrix are made of the same or different materials. For example, the solder bumps 25′ located in the outer region of the matrix are made of tin/lead (Sn/Pb), while the solder bumps 25 located in the inner region of the matrix are made of tin/silver (Sn/Ag). The solder bumps 25′ located in the outer region of the matrix have a material stress less than that of the solder bumps 25 located in the inner region of the matrix. The solder bumps 25 located in the inner region of the matrix are formed first by printing or ball implantation and then the solder bumps 25′ located in the outer region of the matrix are formed by printing or ball implantation.

According to another embodiment, the package structure comprises: a substrate body 20, wherein a plurality of matrix-arranged electrical contact pads 201 are formed on at least one surface 20a of the substrate body, a solder mask layer 21 is formed on the surface 20a and has a plurality of openings 210 for exposing the electrical contact pads 201, respectively; a first electroless-plated layer 22 disposed on the electrical contact pads 201, on the walls of the openings 210, and at the peripheries of the openings 210; a second electroless-plated layer 24 disposed on the first electroless-plated layer 22, wherein the first electroless-plated layer 22 and the second electroless-plated layer 24 constitute a recessed electrical connection structure, a plurality of solder bumps 25 are disposed on the second electroless-plated layer 24, which is made of tin (Sn), lead (Pb), silver (Ag), copper (Cu), zinc (Zn), bismuth (Bi), nickel (Ni), palladium (Pd), or gold (Au); and a semiconductor chip 26 mounted on the second electroless-plated layer 24, wherein the semiconductor chip 26 has an active surface 26a with a plurality of electrode pads 261 thereon, a plurality of metal bumps 29 made of gold (Au), copper (Cu), nickel (Ni), or lead (Pb) are disposed on the electrode pads 261 and electrically connected to the solder bumps 25, and an underfill material 28 is filled between the semiconductor chip 26 and the solder mask layer 21.

In the above-described package structure, the solder mask layer 21 is made of a photosensitive resin or non-photosensitive resin such as green paint or a dielectric layer. The first electroless-plated layer 22 is made of copper (Cu), and the second electroless-plated layer 24 is made of tin (Sn), nickel/palladium/gold (Ni/Pd/Au), or nickel/gold (Ni/Au).

As described above, the solder bumps 25′ located in the outer region of the matrix are larger than the solder bumps 25 located in the inner region of the matrix. Meanwhile, the solder bumps 25″ located in the corner regions of the matrix are larger than the solder bumps 25′ that are located in the other regions of the matrix. The solder bumps of different sizes are formed by screen printing using a screen mask with openings of different sizes or implanting balls of different sizes. Further, the solder bumps 25′ located in the outer region of the matrix and the solder bumps 25 located in the inner region of the matrix are made of the same or different materials. For example, the solder bumps 25′ located in the outer region of the matrix are made of tin/lead (Sn/Pb), while the solder bumps 25 located in the inner region of the matrix are made of tin/silver (Sn/Ag). The solder bumps 25′ located in the outer region of the matrix have a material stress less than that of the solder bumps 25 located in the inner region of the matrix. The solder bumps 25 located in the inner region of the matrix are formed first by printing or ball implantation and then the solder bumps 25′ located in the outer region of the matrix are formed by printing or ball implantation.

Therefore, the present invention mainly involves forming even electroless-plated layers on the electrical contact pads of the substrate body so as to overcome the conventional drawbacks of breakage of interfaces between the solder bumps and the electrical contact pads and even damage of the whole package structure caused by excessive differences in stress between the solder bumps during packaging and reliability tests due to different heights, areas and sizes of the solder bumps. Further, the first and second electroless-plated layers are formed in a much wider area than the electrical contact pads so as to increase the area of contact with the solder bumps, thereby increasing the bonding force between the semiconductor chip and the substrate body. Furthermore, by increasing sizes or decreasing stresses of the solder bumps located in the outer region or corner regions of matrix, the stresses applied on the solder bumps are balanced so as to increase the reliability of the package structure.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A package structure, comprising:
a substrate body with at least a surface thereof having a plurality of electrical contact pads arranged thereon in a matrix, the surface having a solder mask layer disposed thereon, wherein the solder mask layer has a plurality of openings for exposing the electrical contact pads, respectively;
a first electroless-plated layer disposed on the electrical contact pads, on walls of the openings and at peripheries of the openings;
a second electroless-plated layer disposed on the first electroless-plated layer, the first and second electroless-plated layers constituting a recessed electrical connection structure;
a semiconductor chip having an active surface with a plurality of electrode pads provided thereon; and
a solder material disposed between the electrode pads and the second electroless-plated layer, filled in the recessed electrical connection structure, and electrically connected to the second electroless-plated layer.

2. The structure of claim 1, wherein the first electroless-plated layer is made of copper (Cu).

3. The structure of claim 1, wherein the second electroless-plated layer is made of one of tin (Sn), nickel/palladium/gold (Ni/Pd/Au), and nickel/gold (Ni/Au).

4. The structure of claim 1, further comprising an underfill material filled between the active surface of the semiconductor chip and the solder mask layer.

5. The structure of claim 1, further comprising a plurality of solder bumps disposed on the second electroless-plated layer and connected to the solder material.

6. The structure of claim 5, wherein the solder bumps located in an outer region of the matrix are larger than the solder bumps located in an inner region of the matrix.

7. The structure of claim 5, wherein the solder bumps located in an outer region of the matrix and the solder bumps located in an inner region of the matrix are made of same or different materials.

8. The structure of claim 5, wherein the solder bumps located in an outer region of the matrix have a material stress less than that of the solder bumps located in an inner region of the matrix.

9. The structure of claim 5, wherein the solder bumps located in corner regions of the matrix are larger than the solder bumps located in other regions of the matrix.

10. A package structure, comprising:
a substrate body with at least a surface thereof having a plurality of electrical contact pads arranged thereon in a matrix, the surface having a solder mask layer disposed thereon, wherein the solder mask layer has a plurality of openings for exposing the electrical contact pads, respectively;
a first electroless-plated layer disposed on the electrical contact pads, on the walls of the openings and at peripheries of the openings;
a second electroless-plated layer disposed on the first electroless-plated layer, the first and second electroless-plated layers constituting a recessed electrical connection structure;
a semiconductor chip having an active surface with a plurality of electrode pads provided thereon, wherein a plurality of metal bumps are provided on the electrode pads and the metal bumps extended into the recessed electrical connection structure constituted by the first and second electroless-plated layers; and
a solder material disposed between the metal bumps and the second electroless-plated layer so as for the solder material to be filled in the recessed electrical connection structure and electrically connected to the second electroless-plated layer.

11. The structure of claim 10, wherein the metal bumps are made of one selected from the group consisting of gold (Au), copper (Cu), nickel (Ni), and lead (Pb).

12. A package structure, comprising:
a substrate body having at least a surface with a plurality of electrical contact pads arranged thereon in a matrix, wherein a solder mask layer is disposed on the surface and has a plurality of openings for exposing the electrical contact pads, respectively;
a first electroless-plated layer disposed on the electrical contact pads, on the walls of the openings and at peripheries of the openings;
a second electroless-plated layer disposed on the first electroless-plated layer, the first and second electroless-plated layers constituting a recessed electrical connection structure;
a plurality of solder bumps disposed on the second electroless-plated layer; and
a semiconductor chip having an active surface with a plurality of electrode pads provided thereon, wherein a plurality of metal bumps are provided on the electrode pads and electrically connected to the solder bumps on the second electroless-plated layer.

13. The structure of claim 12, wherein the metal bumps are made of one selected from the group consisting of gold (Au), copper (Cu), nickel (Ni), and lead (Pb).

14. A package substrate, comprising:
a substrate body having at least a surface with a plurality of electrical contact pads arranged thereon in a matrix, wherein a solder mask layer is disposed on the surface and has a plurality of openings for exposing the electrical contact pads, respectively;
a first electroless-plated layer disposed on the electrical contact pads, on the walls of the openings and at peripheries of the openings; and
a second electroless-plated layer disposed on the first electroless-plated layer, the first and second electroless-plated layers constituting a recessed electrical connection structure.

15. The substrate of claim 14, wherein the first electroless-plated layer is made of copper (Cu).

16. The substrate of claim 14, wherein the second electroless-plated layer is made of one of tin (Sn), nickel/palladium/gold (Ni/Pd/Au), and nickel/gold (Ni/Au).

17. The substrate of claim 14, further comprising a plurality of solder bumps disposed on the second electroless-plated layer.

18. The substrate of claim 17, wherein the solder bumps located in an outer region of the matrix are larger than the solder bumps located in an inner region of the matrix.

19. The substrate of claim 17, wherein the solder bumps located in an outer region of the matrix and the solder bumps located in an inner region of the matrix are made of same or different materials.

20. The substrate of claim 17, wherein the solder bumps located in an outer region of the matrix has a material stress less than that of the solder bumps located in an inner region of the matrix.

21. The substrate of claim 17, wherein the solder bumps located in corner regions of the matrix are larger than the solder bumps located in other regions of the matrix.
